(19) United States
(12) Patent Application Publication
(10) Pub. No.: US 2017/0373242 A1
(43) Pub. Date: Dec. 28, 2017

(54) MEMS DEVICE, PIEZOELECTRIC ACTUATOR, AND ULTRASONIC MOTOR

(71) Applicant: SEIKO EPSON CORPORATION, Tokyo (JP)

(72) Inventors: Daisuke YAMADA, Shiojiri-shi (JP); Eiju HIRAI, Azumino-shi (JP); Akio KONISHI, Matsumoto-shi (JP)

(21) Appl. No.: 15/628,816

(22) Filed: Jun. 21, 2017

(30) Foreign Application Priority Data
Jun. 24, 2016 (JP) 2016-125257

(51) Int. Cl. H01L 41/08; H01L 41/187; H01L 41/083; H02N 2/02; H01L 41/297; G11B 21/16; H02N 2/00

(52) U.S. Cl. CPC H01L 41/0815; H01L 41/083; H01L 41/1876; H02N 2/026; G11B 21/16; H02N 2/002; H01L 41/297

(57) ABSTRACT

In a MEMS device in which a first electrode layer, a piezoelectric layer, and a second electrode layer are stacked in this order from a first surface side of a substrate, a first wiring layer is stacked on a second surface on a side opposite to a first surface of the substrate and the first electrode layer and the first wiring layer are connected to each other via a through wiring passing through the substrate.

### CROSS-REFERENCE TO RELATED APPLICATIONS

The present application claims priority to Japanese Patent Application No. 2016-125257, filed Jun. 24, 2016, which is hereby incorporated by reference in its entirety.

### BACKGROUND

### 1. Technical Field

The present invention relates to a MEMS device including a piezoelectric layer sandwiched between two electrodes, a piezoelectric actuator, and an ultrasonic motor.

### 2. Related Art

Piezoelectric actuators, which are a type of Micro Electro Mechanical Systems (MEMS) device including piezoelectric elements, are applied to driving portions of robots or various devices. The piezoelectric element includes two electrodes and a piezoelectric layer sandwiched therebetween and is deformed by application of a voltage to both electrodes. The piezoelectric actuator utilizes the deformation of the piezoelectric element to drive a driven object such as a rotor which is in contact with the piezoelectric actuator. For example, an ultrasonic motor to which a piezoelectric actuator is applied is formed by stacking a substrate on which a plurality of piezoelectric elements are formed and a vibrating plate on which protrusions for rotating the rotor are formed (see JP-A-2016-40993). In such an ultrasonic motor, the vibrating plate is deformed to cause the protrusions to be reciprocated or be elliptically moved, by a plurality of piezoelectric elements being selectively deformed. The rotor is rotated by transmitting the motion of the protrusion to the rotor.

An example of a structure of a piezoelectric actuator of the related art will be described in detail with reference to FIG. 16 and FIG. 17. FIG. 16 is a plan view illustrating the piezoelectric actuator 89, and FIG. 17 is a sectional view taken along line XVII-XVII in FIG. 16. In addition, in FIG. 16, a wiring layer 99 on an outermost surface (uppermost surface) is indicated by hatching. As illustrated in FIG. 16, a piezoelectric element 91 formed long in a longitudinal direction of the substrate 90 at a center in a width direction (that is, the transverse direction) of the substrate 90 and piezoelectric elements 91 formed on positions of four corners of the substrate 90, which are smaller than the central piezoelectric element 91 are disposed on the substrate 90 of the piezoelectric actuator 89. As illustrated in FIG. 17, these five piezoelectric elements 91 are formed by a first electrode layer 94, a piezoelectric layer 95, and a second electrode layer 96 being stacked in this order from an oxide film 93 side on the oxide film 93 stacked on an entire surface of the substrate 90. The first electrode layer 94 and the second electrode layer 96 are thin-film electrodes formed by a sputtering method or the like, for example. The piezoelectric layer 95 and the second electrode layer 96 are formed for each individual piezoelectric element 91. In other words, the piezoelectric layer 95 and the second electrode layer 96 are formed at positions corresponding to the respective piezoelectric elements 91. On the other hand, the first electrode layer 94 is formed over substantially the entire surface of the substrate 90 as an electrode layer common to the five piezoelectric elements 91. In addition, the insulating layer 97 made of silicon oxide or the like is formed over substantially the entire surface of the substrate 90 by a CVD method or the like, for example, so as to cover the first electrode layer 94, the piezoelectric layer 95, and the second electrode layer 96. Further, a contact hole 98 from which the insulating layer 97 is removed is formed at a position corresponding to the second electrode layer 96 on each piezoelectric element 91 and at a position corresponding to the first electrode layer 94 at a position deviated from the piezoelectric element 91. By the contact hole 98, the wiring layer 99 stacked on the insulating layer 97 and the second electrode layer 96 or the first electrode layer 94, which corresponds to the wiring layer 99, are electrically connected.

For example, as illustrated in FIG. 16, the wiring layer 99 is formed on three regions. Specifically, a wiring layer 99a electrically connected to the piezoelectric element 91 positioned at the center of the substrate 90 and the second electrode layer 96 on the piezoelectric element 91 positioned at one diagonal (upper left and lower right in FIG. 16) of the substrate 90, a wiring layer 99b electrically connected to the second electrode layer 96 on the piezoelectric element 91 positioned at the other diagonal (lower left and upper right in FIG. 16) of the substrate 90, and a wiring layer 99c electrically connected to the first electrode layer 94 common to each piezoelectric elements 91 are formed. Accordingly, the same voltage is applied to the piezoelectric elements 91 positioned at the center and one diagonal and the piezoelectric elements 91 vibrate in the same phase. In addition, the same voltage is applied to the piezoelectric elements 91 positioned at the other diagonal and the piezoelectric elements 91 vibrate in the same phase. The protrusion 100 attached to the piezoelectric actuator 89 reciprocates and elliptically moves, by making a phase of vibration of the piezoelectric element 91 positioned at the center and one diagonal and a phase of vibration of the piezoelectric element 91 positioned at the other diagonal different from each other.

By the way, in the structure described above, a layout (that is, routing) of a wiring layer 99 is restricted, since a plurality of wiring layers 99 are formed on one surface of the substrate 90. Therefore, wiring resistance (also referred to as electric resistance) is likely to increase up to the piezoelectric element 91 through the wiring layer 99. Specifically, as illustrated in FIG. 17, since the wiring layer 99c electrically connected to the first electrode layer 94 is formed at a position deviated from the piezoelectric element 91 by avoiding the wiring layer 99a electrically connected to the second electrode layer 96, the first electrode layer 94 is extended to an outside of the piezoelectric element 91. In other words, a wiring which is made of only the first electrode layer 94 and is to be thin and have high resistance is formed. There are risk that voltage drop increases at a portion including only the first electrode layer 94 and that a sufficient voltage cannot be supplied to the piezoelectric element 91. In addition, since the wiring layer 99 at the position deviating from the piezoelectric element 91 such as between the piezoelectric elements 91 in the wiring layers 99 electrically connected to the second electrode layer 96 faces to the first electrode layer 94 with the thin insulating layer 97 interposed therebetween, a parasitic capacitance is formed on the portion. As a result, there is a risk that a problem such as noise or delay of a drive signal is generated. In addition, there is a risk that electric field intensity between the second electrode layer 96 and the first electrode layer 94 in the portion is increased and that a problem such as dielectric breakdown is generated.

### SUMMARY

An advantage of some aspects of the invention is to provide a MEMS device in which voltage drop or the like is suppressed, a piezoelectric actuator, and an ultrasonic motor.

According to an aspect of the invention, in a MEMS device in which a first electrode layer, a piezoelectric layer, and a second electrode layer are stacked in this order from a first surface side of a substrate, a first wiring layer is stacked on a second surface on a side opposite to a first surface of the substrate and the first electrode layer and the first wiring layer are connected to each other via a through wiring passing through the substrate.

According to the invention, since the first wiring layer is formed on the second surface on the side opposite to the first surface on which the piezoelectric layer is formed, a degree of freedom in design increases. In other words, the first wiring layer can be formed without interfering with wirings such as the second electrode layer formed on the first surface and the second wiring layer electrically connected to the second electrode layer. Accordingly, a region in which the first wiring layer is formed or the like can be increased as much as possible and wiring resistance (electric resistance) of the first wiring layer can be suppressed. As a result, voltage drop is suppressed in the first electrode layer overlapping the piezoelectric layer.

In the configuration, it is preferable that the through wiring overlap the piezoelectric layer in a stacking direction of the first electrode layer, the piezoelectric layer, and the second electrode layer.

According to the configuration, since the first electrode layer may not be routed to an outside of the piezoelectric layer, the wiring resistance can be suppressed. In other words, film thickness is unlikely to be increased and the region (wiring portion) made only of the first electrode layer of which the wiring resistance is likely to be increased can be reduced. As a result, the voltage drop is further suppressed in the first electrode layer overlapping the piezoelectric layer.

In addition, in each configuration described above, it is preferable that the through wiring overlap a region in which the first electrode layer, the piezoelectric layer, and the second electrode layer overlap each other in the stacking direction.

According to the configuration, the wiring resistance can be suppressed since the first electrode layer may be not routed to the outside of a region in which the first electrode layer, the piezoelectric layer, and the second electrode layer overlap each other.

Further, in any of the above configurations, it is preferable that at least a portion of the first wiring layer be buried in the substrate.

According to the configuration, the wiring resistance of the first wiring layer can be suppressed while increase in the thickness of the MEMS device is suppressed.

In any of the above configurations, it is preferable that the first electrode layer and the first wiring layer be connected via a plurality of through wirings.

According to the configuration, the adhesion of the first wiring layer can be improved as compared with a case where the first electrode layer and the first wiring layer are connected by one through wiring. Accordingly, peeling of the first wiring layer from the substrate can be suppressed.

In addition, according to another aspect of the invention, in a MEMS device in which a first electrode layer, a piezoelectric layer, and a second electrode layer are stacked in this order from a first surface side of a substrate, a resin layer covering the first electrode layer, the piezoelectric layer, and the second electrode layer and a second wiring layer stacked at least on a portion of the resin layer are formed on the first surface of the substrate, and the second electrode layer and the second wiring layer are connected to each other via a contact hole formed on the resin layer.

According to the configuration, the first electrode layer and the second wiring layer can be separated from each other by the resin layer. Therefore, parasitic capacitance formed between the first electrode layer and the second wiring layer can be suppressed. In addition, electric field strength between the first electrode layer and the second wiring layer can be suppressed. Accordingly, the second wiring layer can be disposed without the pattern of the first electrode layer being avoided and the degree of freedom in design increases. As a result, a region in which the second wiring layer is formed or the like can be increased as much as possible, and wiring resistance of the second wiring layer can be suppressed.

In addition, in the configuration, it is preferable that the contact hole overlap the piezoelectric layer in a stacking direction of the first electrode layer, the piezoelectric layer, and the second electrode layer.

According to the configuration, since the second electrode layer may not be routed to the outside of the piezoelectric layer, the wiring resistance can be suppressed. In other words, film thickness is unlikely to be increased and the region (wiring portion) made only of the second electrode layer of which the wiring resistance is likely to be increased can be reduced.

Further, in any of the above configurations, it is preferable that at least a portion of the second wiring layer be buried in the resin layer.

According to the configuration, the wiring resistance of the second wiring layer can be suppressed while increase in the thickness of the MEMS device is suppressed.

In any of the above configurations, it is preferable that the second electrode layer and the second wiring layer be connected via the plurality of contact holes.

According to the configuration, the adhesion of the second wiring layer can be improved as compared with a case where the second electrode layer and the second wiring layer are connected by one contact hole. Accordingly, peeling of the second wiring layer from the resin layer can be suppressed.

Further, according to still another aspect of the invention, a piezoelectric actuator which deforms the piezoelectric layer by forming an electric field between the first electrode layer and the second electrode layer and deforms the substrate by deformation of the piezoelectric layer includes the structure of the MEMS device according to any of the above configurations.

According to the configuration, output of the piezoelectric actuator can be increased.

Further, according to still another aspect of the invention, an ultrasonic motor including a protrusion of which position changes according to the deformation of the substrate; and a rotating object which abuts against the protrusion and rotates according to a change of the protrusion includes the structure of the piezoelectric actuator according to the configuration.

According to the configuration, output of the ultrasonic motor can be increased.

### BRIEF DESCRIPTION OF THE DRAWINGS

The invention will be described with reference to the accompanying drawings, wherein like numbers reference like elements.

FIG. 1 is a plan view illustrating a configuration of an ultrasonic motor.

FIG. 2 is a front view illustrating the configuration of the ultrasonic motor.

FIG. 3 is an exploded perspective view illustrating a driving device.

FIG. 4 is a plan view illustrating a piezoelectric actuator as viewed from a piezoelectric element side.

FIG. 5 is a plan view illustrating the piezoelectric actuator viewed from the side opposite to the piezoelectric element.

FIG. 6 is a schematic sectional view taken along line VI-VI.

FIG. 7 is a schematic diagram illustrating an operation of the ultrasonic motor.

FIG. 8 is a process diagram illustrating a method for manufacturing a piezoelectric actuator.

FIG. 9 is a process diagram illustrating the method for manufacturing the piezoelectric actuator.

FIG. 10 is a process diagram illustrating the method for manufacturing the piezoelectric actuator.

FIG. 11 is a process diagram illustrating the method for manufacturing the piezoelectric actuator.

FIG. 12 is a schematic sectional view of a piezoelectric actuator according to a second embodiment.

FIG. 13 is a process diagram illustrating a method of manufacturing the piezoelectric actuator according to the second embodiment.

FIG. 14 is a process diagram illustrating the method of manufacturing the piezoelectric actuator according to the second embodiment.

FIG. 15 is a process diagram illustrating a method for manufacturing a piezoelectric actuator according to a third embodiment.

FIG. 16 is a plan view illustrating a configuration of a piezoelectric actuator of the related art.

FIG. 17 is a schematic sectional view taken along line XVII-XVII.

### DESCRIPTION OF EXEMPLARY EMBODIMENTS

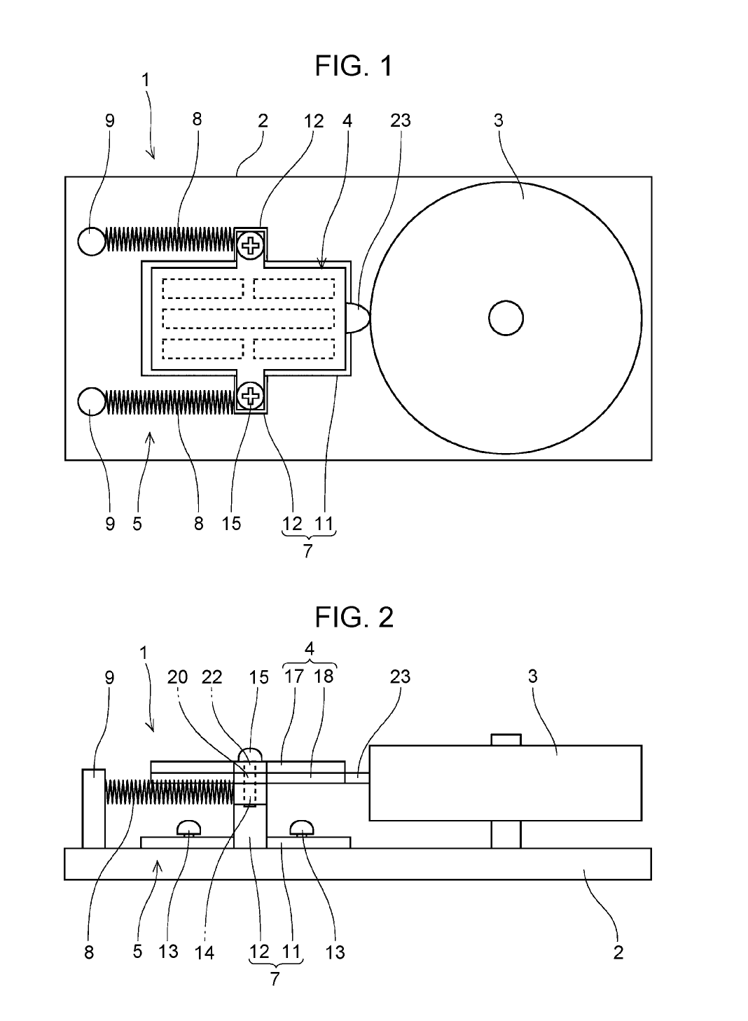

Hereinafter, aspects for realizing the invention will be described with reference to the attached drawings. In the embodiments described below, although various limitations have been made as preferred specific examples of the invention, the scope of the invention is not limited to the aspects unless specifically stated to limit the invention in the following description. In addition, in the following description, an ultrasonic motor 1 including a piezoelectric actuator 17, which is one type of MEMS device of the invention, will be described as an example. FIG. 1 is a plan view illustrating a configuration of the ultrasonic motor 1. In addition, FIG. 2 is a front view illustrating the configuration of the ultrasonic motor 1.

The ultrasonic motor 1 is configured by a base 2, a rotor 3 which is a kind of rotating object, a driving device 4 which rotates the rotor 3, a holding mechanism 5 which holds the driving device 4, and the like. The rotor 3 has a columnar shape and is rotatably supported by a shaft on one surface (surface on which driving device 4 is disposed) of the base 2. The holding mechanism 5 includes a slide member 7 to which the driving device 4 is attached, a biasing member 8 such as a coil spring of which one end is fixed to the slide member 7, and a support pin 9 which protrudes from a surface of the base 2 and to which the other end of the biasing member 8 is fixed.

The slide member 7 includes a base portion 11 which is slidably supported with respect to the base 2 and a pair of supporting portions 12 which stand on a side opposite to the base 2 from the base portion 11. In the present embodiment, the base portion 11 includes two slide holes (not illustrated) long in a sliding direction. A slide pin 13 fixed to the base 2 is inserted through the slide hole. In other words, the slide member 7 is held in a slidable state in a longitudinal direction by the slide pin 13 inserted through the slide hole. The supporting portion 12 is formed at both ends of the base 2 in a direction orthogonal to the sliding direction (transverse direction). A screw fixing hole 14 corresponding to screw insertion holes (specifically, a vibrating plate-side screw insertion hole 20 and an actuator-side screw insertion hole 22) of the driving device 4 (which will be described below) is formed on a tip side (that is, side opposite to base 2) of the supporting portion 12. The driving device 4 is fixed to the supporting portion 12 by screwing a screw 15 inserted through the screw insertion hole of the driving device 4 into the screw fixing hole 14. The biasing member 8 is disposed in the sliding direction of the slide member 7 between the supporting portion 12 and the support pin 9. One end of the biasing member 8 is fixed to the supporting portion 12 and the other end thereof is fixed to the support pin 9 to bias the slide member 7 toward the rotor 3. Accordingly, a protrusion 23 (which will be described below) of the driving device 4 attached to the slide member 7 becomes a state of being pressed against the rotor 3.

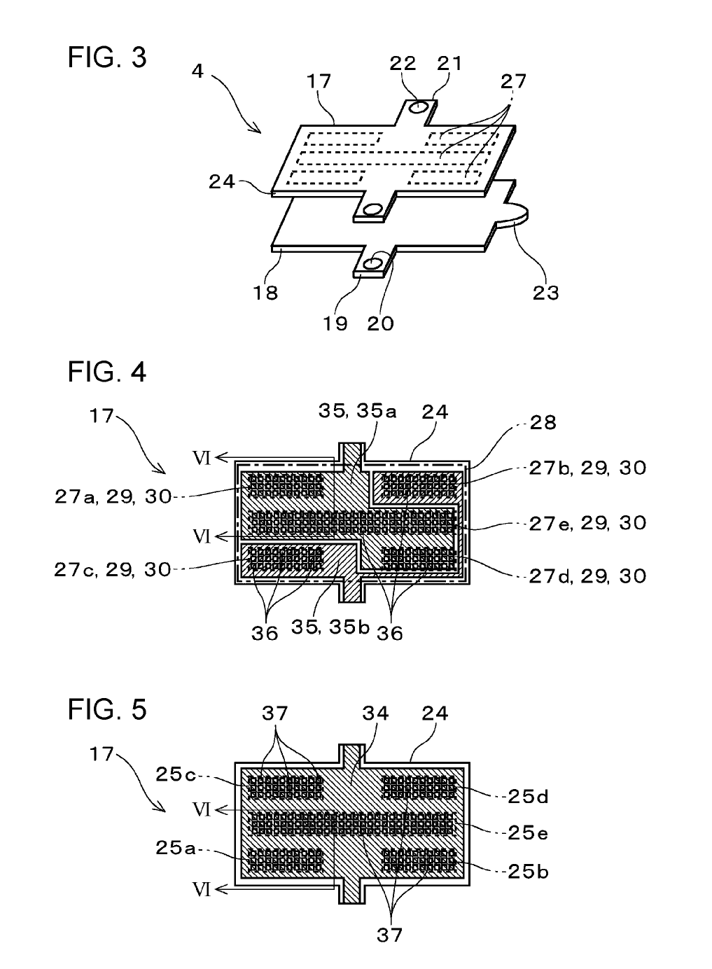

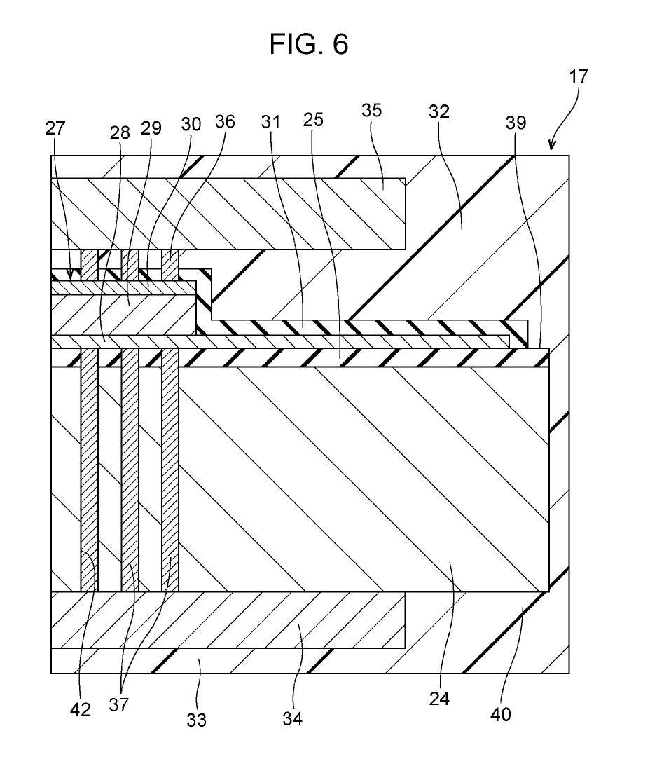

Next, the driving device 4 will be described. FIG. 3 is an exploded perspective view illustrating the driving device 4. FIG. 4 is a plan view illustrating the piezoelectric actuator 17 as viewed from the piezoelectric element 27 side. FIG. 5 is a plan view illustrating the piezoelectric actuator 17 as viewed from a side opposite to the piezoelectric element 27. FIG. 6 is a schematic sectional view taken along line VI-VI in FIG. 4 and FIG. 5. In FIG. 4 and FIG. 5, an uppermost surface of the wiring layer (specifically, first wiring layer 34 or second wiring layer 35) is illustrated by hatching.

As illustrated in FIG. 3, according to the embodiment, the driving device 4 includes a metallic vibrating plate 18 and a piezoelectric actuator 17 in which a piezoelectric element 27 or the like is formed on a silicon substrate 24. In the embodiment, the vibrating plate 18 is a plate member which is adhered to a surface (first surface 39 which is will be described below) of a side on which the piezoelectric element 27 of the piezoelectric actuator 17 is formed and has a rectangular shape in a plan view. The piezoelectric actuator 17 can be reinforced by the vibrating plate 18. In addition, a vibrating plate connecting portion 19 is formed at both ends in a direction orthogonal to the sliding direction of the vibrating plate 18. A vibrating plate-side screw insertion hole 20 corresponding to the screw fixing hole 14 of the supporting portion 12 is opened in the vibrating plate connecting portion 19. Further, a protrusion 23 which abuts against (is in contact with) the rotor 3 is formed on a central portion of a direction orthogonal to the sliding direction in a side of the rotor 3-side of the vibrating plate 18. The protrusion 23 is a member for abutting against the rotor 3 and applying rotating force to the rotor 3. The vibrating plate 18 can be formed of a metal material such as stainless steel, aluminum, aluminum alloy, titanium, a titanium alloy, copper, a copper alloy, an iron-nickel alloy, or the like. In addition, the protrusion 23 can be integrally formed with the vibrating plate 18 or can be formed of a more durable member.

In the embodiment, the piezoelectric actuator 17 is a rectangular plate member which has substantially the same shape as the vibrating plate 18 except for the protrusion 23 in a plan view. Like the vibrating plate 18, actuator connecting portions 21 are formed at both ends of the vibrating plate 18 in a direction orthogonal to the sliding direction. An actuator-side screw insertion hole 22 corresponding to the vibrating plate-side screw insertion hole 20 is opened in the actuator connecting portion 21. In other words, in a state where the vibrating plate 18 and the piezoelectric actuator 17 overlap each other, the vibrating plate-side screw insertion hole 20 and the actuator-side screw insertion hole 22 communicate with each other. The driving device 4 is fixed to the slide member 7 by fixing the screw 15 to the screw fixing hole 14 of the supporting portion 12 through the vibrating plate-side screw insertion hole 20 and the actuator-side screw insertion hole 22.

A piezoelectric element 27 is formed on a surface (hereinafter referred to as first surface 39) of a side facing the vibrating plate 18 of the substrate 24 constituting the piezoelectric actuator 17. In the embodiment, five piezoelectric elements 27a to 27e are formed. Specifically, the piezoelectric element 27e formed long in the longitudinal direction (that is, in sliding direction) of the piezoelectric actuator 17 in the center of the piezoelectric actuator 17 (that is, direction orthogonal to sliding direction) in the transverse direction and the piezoelectric elements 27a to 27d in which the dimension in the longitudinal direction is formed to be smaller than the central piezoelectric element 27e are disposed on four corners of the electric actuator.

As illustrated in FIG. 6, in each of the piezoelectric elements 27a to 27e, a first electrode layer 28, a piezoelectric layer 29 and a second electrode layer 30 are sequentially stacked from a first surface 39 side of the substrate 24 (more specifically, oxide film 25 side formed on the first surface 39 of substrate 24) in this order. The first electrode layer 28 is an electrode common to the piezoelectric elements 27a to 27e and is formed substantially on an entire surface of the substrate 24, as illustrated in FIG. 4. On the other hand, the piezoelectric layer 29 and the second electrode layer 30 are individual electrodes for each of the piezoelectric elements 27a to 27e, and are formed on a region on which the piezoelectric elements 27 are disposed. In other words, the piezoelectric layer 29 and the second electrode layer 30 define a shape of each of the piezoelectric elements 27a to 27e. The first electrode layer 28 can be an individual electrode and the second electrode layer 30 can be a common electrode depending on circumstances of a driving circuit and wiring. When an electric field corresponding to a potential difference between both the electrodes is applied between the first electrode layer 28 and the second electrode layer 30, the piezoelectric element 27 configured described above vibrates to be expanded and contracted (that is, moves to be expanded and contracted) in the longitudinal direction due to the piezoelectric transverse effect.

In addition, as illustrated in FIG. 6, an inorganic protective film 31 so as to cover the entirety of the first electrode layer 28, the piezoelectric layer 29, and the second electrode layer 30, including the piezoelectric element 27 and a first resin layer 32 (corresponding to a resin layer in the invention) covering the inorganic protective film 31 are stacked in this order. A second wiring layer 35 electrically connected to the second electrode layer 30 is buried in an inside portion of the first resin layer 32. In the embodiment, the first resin layer 32 is formed on an upper surface and a lower surface of the second wiring layer 35. In other words, the second wiring layer 35 is stacked between the first resin layers 32. Therefore, the inorganic protective film 31 and the first resin layer 32 are disposed between the first electrode layer 28, the piezoelectric layer 29, and the second electrode layer 30 and the second wiring layer 35. In addition, a plurality of contact holes 36 are formed on a position corresponding to the piezoelectric element 27 (specifically, a region overlapping the piezoelectric layer 29 in a stacking direction of the first electrode layer 28, the piezoelectric layer 29, and the second electrode layer 30) which connect the second electrode layer 30 and the second wiring layer 35 to each other by removing the inorganic protective film 31 and the first resin layer 32 between the second electrode layer 30 and the second wiring layer 35. In the embodiment, a diameter of the contact hole 36 is formed to be sufficiently smaller than a dimension of the piezoelectric element 27 in the longitudinal direction and the transverse direction. As illustrated in FIG. 4, the contact hole 36 is evenly (in other words, uniformly) disposed on the entirety of an region on which the second electrode layer 30 is formed, that is, an region on which the piezoelectric layer 29 is formed.

In the embodiment, the second wiring layer 35 is divided into two systems and different voltages are applied to both systems. A second wiring layer 35a on a side is formed across the piezoelectric elements 27a and 27d disposed on one diagonal position (upper left and lower right in FIG. 4) of the substrate 24. Specifically, as illustrated in FIG. 4, the second wiring layers 35a on a side is disposed so as to connect the second electrode layer 30 of the piezoelectric element 27a disposed in an upper left corner, the second electrode layer 30 of the piezoelectric element 27e disposed on the center, and the second electrode layer 30 of the piezoelectric element 27d disposed in a lower right corner with each other. A second wiring layer 35b on the other side is formed across the piezoelectric elements 27c and 27b disposed at the other diagonal position (lower left and upper right in FIG. 4) of the substrate 24. Specifically, the second wiring layer 35b on the other side is disposed to connect the second electrode layer 30 of the piezoelectric element 27c disposed at a lower left corner, the second electrode layer 30 of the piezoelectric element 27b disposed at an upper right corner to each other while avoiding the second wiring layer 35a which is positioned on a side. In other words, the second wiring layer 35b on the other side extends from a position corresponding to the piezoelectric element 27c disposed on the lower left corner to a position corresponding to the piezoelectric element 27b disposed on the upper right corner while being routed around an outside of the second wiring layer 35a on a side on the piezoelectric element 27d disposed at the lower right corner. The second wiring layer 35 is connected to an external wiring (not illustrated) at the end portion of the substrate 24 such as the actuator connecting portion 21 or the like.

In addition, as illustrated in FIG. 6, a first wiring layer 34 connected to the first electrode layer 28 is stacked on a surface (hereinafter, referred to as second surface 40) of a side opposite to a surface (first surface 39) on which the piezoelectric element 27 of the substrate 24 constitutes the piezoelectric actuator 17 is formed. As illustrated in FIG. 5, in the embodiment, the first wiring layer 34 is substantially formed on an entire surface of the second surface 40 of the substrate 24. Further, as illustrated in FIG. 6, the first wiring layer 34 is connected to the first electrode layer 28 via the through wiring 37 passing through the substrate 24. The through wiring 37 forms a conductor similar to the first wiring layer 34 in an inside portion of the through hole 42 passing through the substrate 24 in a thickness direction. In the embodiment, an inner diameter of the through hole 42, that is, an diameter of the through wiring 37 is formed to be sufficiently smaller than the dimension of the piezoelectric element 27 in the longitudinal direction and the transverse direction. In addition, a plurality of through wirings 37 are formed on a region corresponding to the piezoelectric element 27. Specifically, as illustrated in FIG. 5, in the embodiment, the through wiring 37 is disposed to be evenly (that is, uniformly) over the entire region overlapping the piezoelectric element 27 (that is, piezoelectric layer 29) in the stacking direction of the first electrode layer 28, the piezoelectric layer 29 and the second electrode layer 30. The first wiring layer 34 is connected to the external wiring (not illustrated) at the end portion of the substrate 24 such as the actuator connecting portion 21 or the like.

Further, as illustrated in FIG. 6, a second resin layer 33 covering the first wiring layer 34 is formed on the second surface 40 of the substrate 24. The second resin layer 33 is formed integrally with the first resin layer 32 covering the second wiring layer 35. In other words, the entire piezoelectric actuator 17 is covered by the first resin layer 32 and the second resin layer 33. Accordingly, the wirings formed on a surface and a back surface of the substrate 24, the piezoelectric element 27, or the like can be protected.

As the oxide film 25, silicon oxide, zirconium oxide, laminates thereof, or the like can be used. In addition, as the first electrode layer 28 and the second electrode layer 30, various metals such as iridium, platinum, titanium, tungsten, nickel, chromium, palladium, and gold, alloys thereof, laminates thereof, or the like are used. Further, as the piezoelectric layer 29, a ferroelectric piezoelectric material such as lead zirconate titanate (PZT), a relaxor ferroelectric added with a metal such as niobium, nickel, magnesium, bismuth, yttrium is used. In addition, a non-lead material such as barium titanate can also be used. In addition, as the inorganic protective film 31, silicon oxide, silicon nitride, aluminum oxide, aluminum nitride, a laminate thereof, or the like can be used. Further, as the resin layer, a photosensitive resin containing epoxy resin, acrylic resin, phenol resin, polyimide resin, silicone resin, styrene resin or the like as a main component, or the like can be used. As the first wiring layer 34 and the second wiring layer 35, copper, titanium, tungsten, an alloy thereof, a laminate thereof, or the like is used.

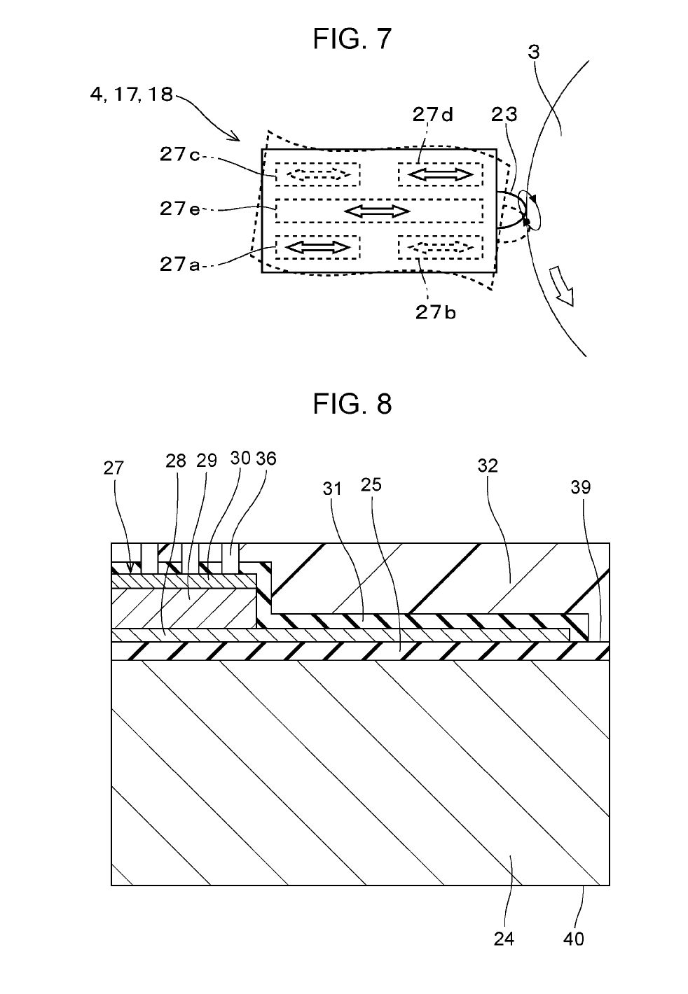

FIG. 7 is a schematic view illustrating an operation of the ultrasonic motor 1 configured as described above. FIG. 7 is a plan view viewed from a surface (that is, second surface 40) aide of a side opposite to the surface on which the piezoelectric element 27 of the piezoelectric actuator 17 is formed. Since the same driving voltage is supplied to the piezoelectric elements 27a and 27d disposed on one diagonal position (a lower left and an upper right in FIG. 7) of the substrate 24 and the piezoelectric element 27e disposed at the center via the second wiring layer 35a, the same electric field is applied to the piezoelectric layers 29 thereof. On the other hand, since the same driving voltage is supplied to the piezoelectric elements 27b and 27c disposed on the other diagonal position (an upper left and a lower right in FIG. 7) of the substrate 24 via the second wiring layer 35b, the same electric field is applied to the piezoelectric layers 29 thereof. In other words, the piezoelectric element groups 27a, 27d, 27e on a side vibrate to be expanded and contracted in the same phase (refer to arrow in FIG. 7) and the piezoelectric element groups 27b and 27c on the other side vibrate to be expanded and contracted with the same phase (see dashed arrows in FIG. 7). The piezoelectric actuator 17 and the vibrating plate 18 adhered thereto are deformed and distorted (refer to dashed line in FIG. 7) and the protrusion 23 provided on the vibrating plate 18 reciprocate or elliptically move, by making the phases of vibration of piezoelectric element groups 27a, 27d, and 27e on a side and the other piezoelectric element groups 27b and 27c on the other side different. As a result, the rotor 3 rotates about axis thereof in a predetermined direction (see arrow in FIG. 7). The rotating direction of the rotor 3 can be reversed from the illustrated direction by the piezoelectric element groups 27b and 27c which are positioned on the other side being driven and either the piezoelectric element groups 27a, 27d, and 27e on a side being not driven or being driven to be weaker than the piezoelectric element groups 27b, 27c on the other side.

As described above, in the embodiment, since the first wiring layer 34 is formed on the second surface 40 of a side opposite to the first surface 39 on which the piezoelectric layer 29 is formed, the degree of freedom in design increases. In other words, the first wiring layer 34 can be formed without interfering with the wirings of the second electrode layer 30, the second wiring layer 35, or the like formed on the first surface 39. Accordingly, a region on which the first wiring layer 34 is formed or the like can be increased as much as possible and wiring resistance (electric resistance) of the first wiring layer 34 can be suppressed. As a result, the voltage drop in the first electrode layer 28 overlapping the piezoelectric layer 29 is suppressed, and the output of the piezoelectric actuator 17, eventually the ultrasonic motor 1, can be increased. In addition, since the through wiring 37 is formed so as to overlap the piezoelectric layer 29 (in the embodiment, region in which first electrode layer 28, piezoelectric layer 29, and second electrode layer 30 overlap each other, that is, piezoelectric element 27), the first electrode layer 28 and the first wiring layer 34 can be connected to each other without routing the first electrode layer 28 to the outside of the piezoelectric layer 29. Accordingly, the film thickness is unlikely to be increased, and a region (wiring portion) formed only of the first electrode layer 28 of which the wiring resistance is likely to be increased can be reduced. As a result, the wiring resistance up to the first electrode layer 28 overlapping the piezoelectric layer 29 can be suppressed, and the voltage drop in the first electrode layer 28 overlapping the piezoelectric layer 29 is further suppressed. Further, since the plurality of through wirings 37 are provided, the adhesion of the first wiring layer 34 can be improved as compared with a case where the first electrode layer 28 and the first wiring layer 34 are connected by one through wiring 37. Accordingly, peeling of the first wiring layer 34 from the substrate 24 can be suppressed.

In addition, since the first electrode layer 28 and the second wiring layer 35 are separated by the first resin layer 32, parasitic capacitance formed between the first electrode layer 28 and the second wiring layer 35 can be suppressed. Furthermore, electric field intensity can be suppressed between the first electrode layer 28 and the second wiring layer 35. Accordingly, the second wiring layer 35 can be disposed without avoiding the pattern of the first electrode layer 28 and thus the degree of freedom in design increases. As a result, the region on which the second wiring layer 35 is formed or the like can be increased as much as possible, and the wiring resistance of the second wiring layer 35 can be suppressed. In addition, since the contact hole 36 is formed so as to overlap the piezoelectric layer 29, the second electrode layer 30 and the second wiring layer 35 can be connected to each other without routing the second electrode layer 30 to the outside of the piezoelectric layer 29. Accordingly, the film thickness is unlikely to be increased, and a region (wiring portion) formed only of the second electrode layer 30 of which the wiring resistance is likely to be increased can be reduced. As a result, the wiring resistance up to the second electrode layer 30 overlapping the piezoelectric layer 29 can be suppressed. Further, since at least a portion of the second wiring layer 35 is buried in the first resin layer 32, the wiring resistance of the second wiring layer 35 can be suppressed while thickening of the plate thickness of the piezoelectric actuator 17 is suppressed. In addition, since the plurality of contact holes 36 are provided, the adhesion of the second wiring layer 35 can be improved as compared with a case where the first electrode layer 28 and the first wiring layer 34 are connected to each other by one contact hole 36. Accordingly, peeling of the second wiring layer 35 from the first resin layer 32 can be suppressed.

Next, a method for manufacturing the piezoelectric actuator 17 will be described. FIG. 8 to FIG. 11 are process diagrams illustrating the method for manufacturing the piezoelectric actuator 17. First, an oxide film 25 is formed on the first surface 39 of the substrate 24. Next, the first electrode layer 28, the piezoelectric layer 29, the second electrode layer 30, or the like are patterned in this order and the piezoelectric elements 27 is formed by a semiconductor process (that is, film formation process, photolithography process, etching process, and the like). In addition, the inorganic protective film 31 is formed so as to cover the piezoelectric elements 27 or the like other than a portion corresponding to the contact hole 36 by the semiconductor process. Further, a portion (lower layer portion) of the first resin layer 32 from which a portion corresponding to the contact hole 36 is removed is formed by a liquid photosensitive adhesive having photosensitivity and thermosetting property being applied to the first surface 39 on which the inorganic protective film 31 is formed by using a spin coater or the like and exposure and development being performed after heating. Accordingly, as illustrated in FIG. 8, the piezoelectric element 27 is covered by the inorganic protective film 31 and the first resin layer 32, and the contact hole 36 is formed on a portion corresponding to the piezoelectric element 27.

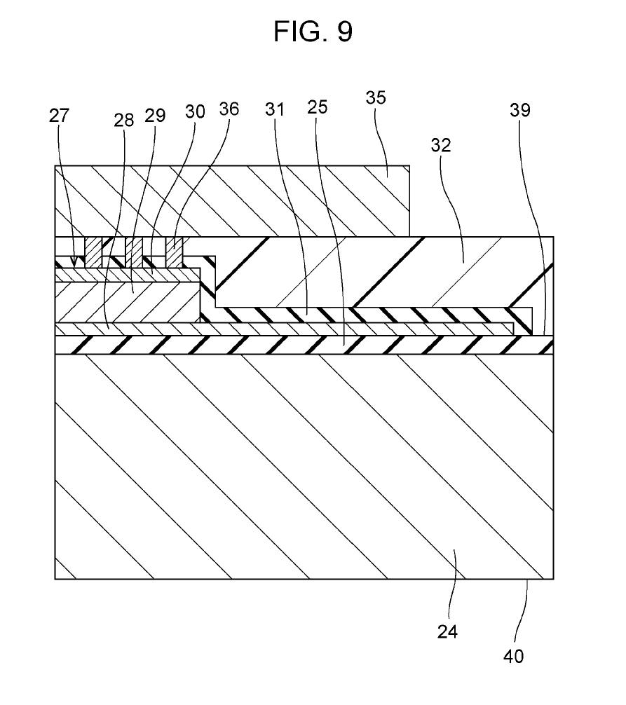

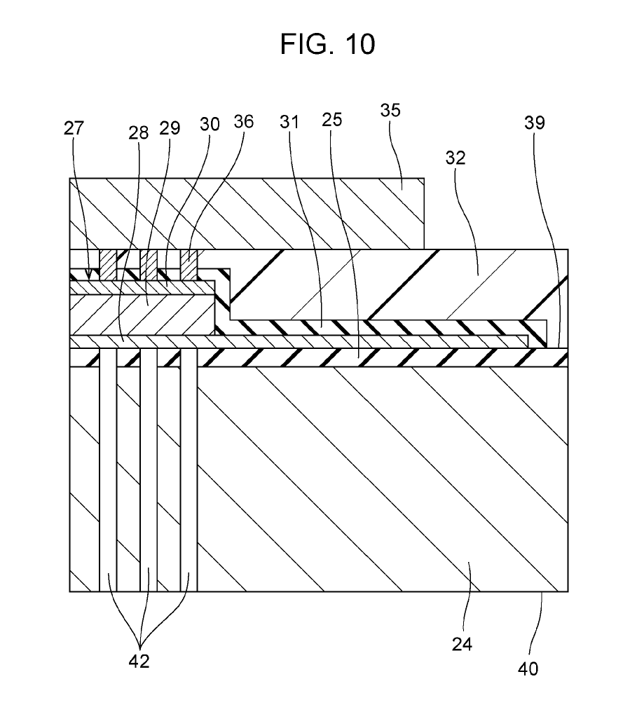

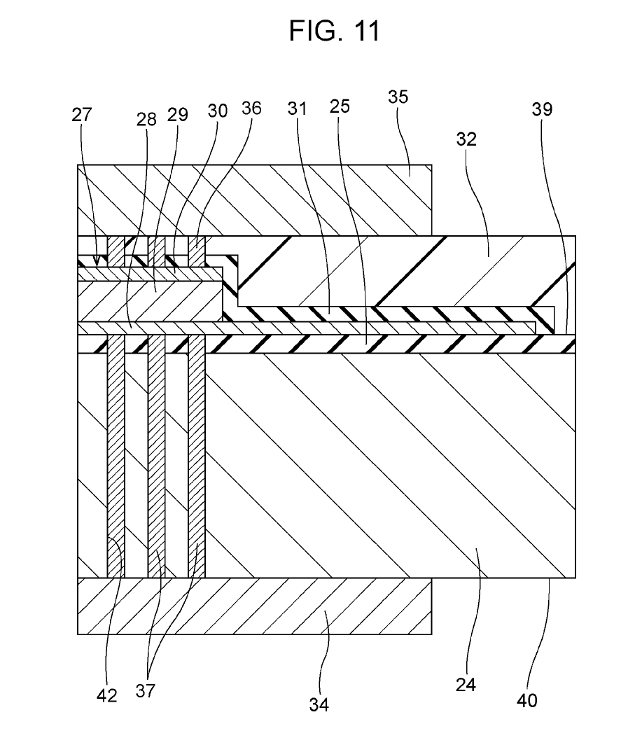

Next, as illustrated in FIG. 9, a second wiring layer 35 is formed on the first resin layer 32 by the semiconductor process or the electroplating method. Here, the second wiring layer 35 and the second electrode layer 30 are electrically connected via the contact hole 36. Next, through wiring 37 is formed from the second surface 40 side. First, as illustrated in FIG. 10, a through hole 42 passing through the substrate 24 and the oxide film 25 is formed. The through hole 42 can be opened for example, by dry etching, laser or the like. Once the through hole 42 is formed, as illustrated in FIG. 11, by the electroplating method, a conductor is formed in the through hole 42 and thus the through wiring 37 is formed therein. The first wiring layer 34 is formed on the second surface 40 by the semiconductor process or the electroplating method. Accordingly, the first wiring layer 34 and the first electrode layer 28 are electrically connected via the through wiring 37. In a case where the first wiring layer 34 is formed by the electroplating method, the through wiring 37 and the first wiring layer 34 can be formed by a single electroplating method. In addition, in a case where the second wiring layer 35 is also formed by the electroplating method, the through wiring 37, the first wiring layer 34 and the second wiring layer 35 can be formed by a single electroplating method. In this case, after the first resin layer 32 is formed, the through hole 42 is formed, and the through wiring 37, the first wiring layer 34, and the second wiring layer 35 are collectively formed by the electroplating method.

Finally, a resin is applied to the entirety including the first surface 39 and the second surface 40 of the substrate 24. In other words, the first resin layer 32 covering the second wiring layer 35 and the second resin layer 33 covering the first wiring layer 34 are formed. Accordingly, the piezoelectric actuator 17 is produced as illustrated in FIG. 6.

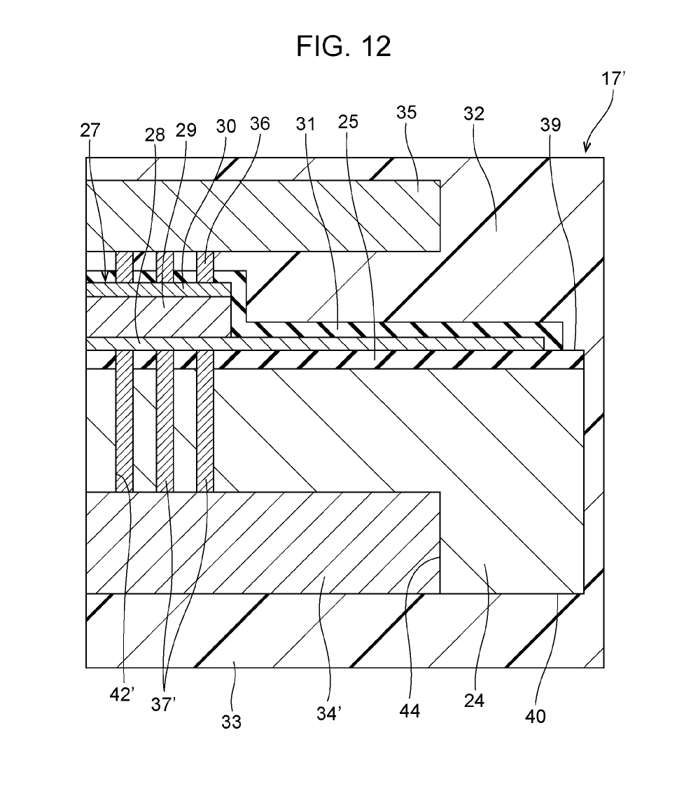

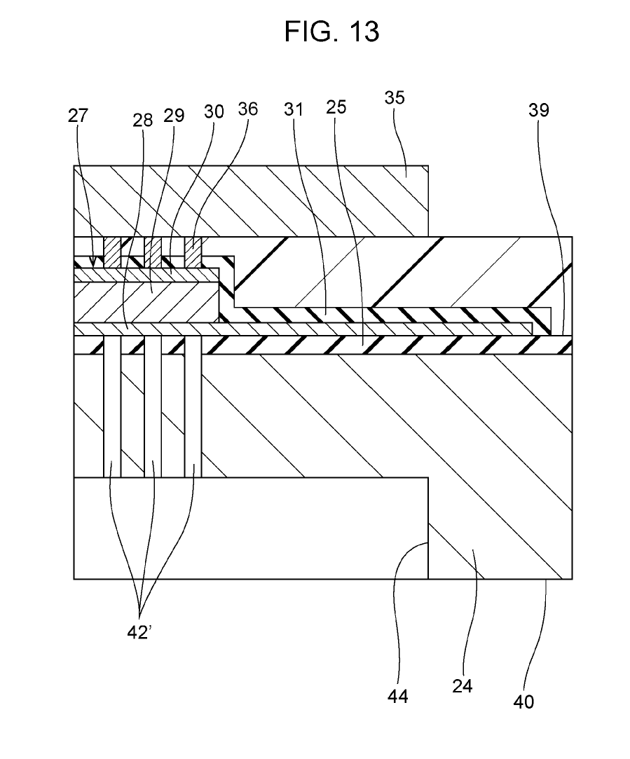

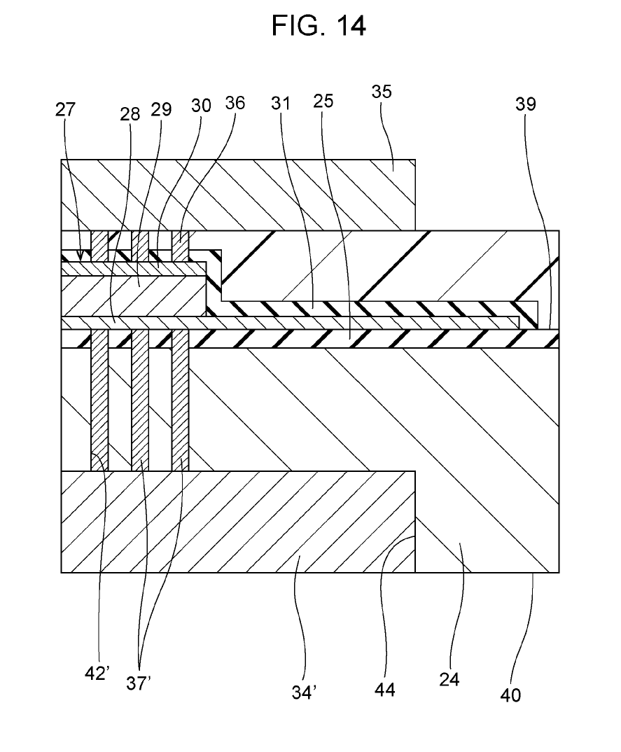

Incidentally, the piezoelectric actuator 17 is not limited to the first embodiment described above. In a piezoelectric actuator 17′ according to a second embodiment illustrated in FIG. 12 to FIG. 14, a first wiring layer 34′ is buried in the substrate 24. Hereinafter, the configuration of the second embodiment will be described in detail. FIG. 12 is a schematic sectional view illustrating the piezoelectric actuator 17′ in the second embodiment, specifically, a sectional view corresponding to a sectional view taken along line VI-VI in the first embodiment. FIG. 13 and FIG. 14 are process diagrams illustrating a method for manufacturing the piezoelectric actuator 17′ in the second embodiment.

As illustrated in FIG. 12, the piezoelectric actuator 17′ in the embodiment has a recessed portion 44 recessed on the second surface 40 of the substrate 24 in a plate thickness direction. A first wiring layer 34′ is formed on the recessed portion 44. The recessed portion 44 in the embodiment is substantially formed on the entire surface except for an outer peripheral edge of the substrate 24 on the second surface 40. Therefore, similar to the first embodiment, the first wiring layer 34′ is substantially formed on the entire surface of the second surface 40. In addition, since the through wiring 37′ passes through the substrate 24 in the region corresponding to the recessed portion 44 and connects the first wiring layer 34′ and the first electrode layer 28 to each other, the distance is decreased compared to the through wiring 37′ of the first embodiment. Therefore, the wiring resistance is decreased than that in the first embodiment. The entirety of the first wiring layer 34′ can be formed so as to be buried in the recessed portion 44, or a portion of the first wiring layer 34′ can be formed to protrude from the recessed portion 44 to an outside (side opposite to piezoelectric element 27) of the second surface 40. Since at least a portion of the first wiring layer 34′ described above is buried in the substrate 24, the wiring resistance of the first wiring layer 34′ can be suppressed while increase in the thickness of the piezoelectric actuator 17′ is suppressed. Since other configurations are the same as those of the first embodiment described above, description thereof will be omitted.

Next, the method for manufacturing the piezoelectric actuator 17′ according to the embodiment will be described. Since formation of the piezoelectric element 27 or the like on the first surface 39 side is the same as that in the first embodiment described above, description thereof will be omitted. When the piezoelectric element 27, the inorganic protective film 31, a portion of the first resin layer 32, the second wiring, and the like are formed on the first surface 39, as illustrated in FIG. 13, the recessed portion 44 and a through hole 42′ are formed on the second surface 40. Specifically, the recessed portion 44 is formed by the anisotropic etching or the like, and then the through holes 42′ are formed by the dry etching, laser or the like. First, the through hole 42′ can be formed by dry etching, laser, or the like and then the recessed portion 44 can be formed by the anisotropic etching or the like. Once the through hole 42′ and the recessed portion 44 are formed, as illustrated in FIG. 14, by the electroplating method, a conductor is formed in the through hole 42′ and the recessed portion 44 and thus the through wiring 37′ and the first wiring layer 34′ are formed therein. The first wiring layer 34′ can be formed separately from the through wiring 37′ by the semiconductor process or the electroplating method. Finally, a resin is applied to the entirety including the first surface 39 and the second surface 40 of the substrate 24. In other words, the first resin layer 32 covering the second wiring layer 35 and the second resin layer 33 covering first wiring layer 34′ are formed. Accordingly, the piezoelectric actuator 17′ as illustrated in FIG. 12 is produced.

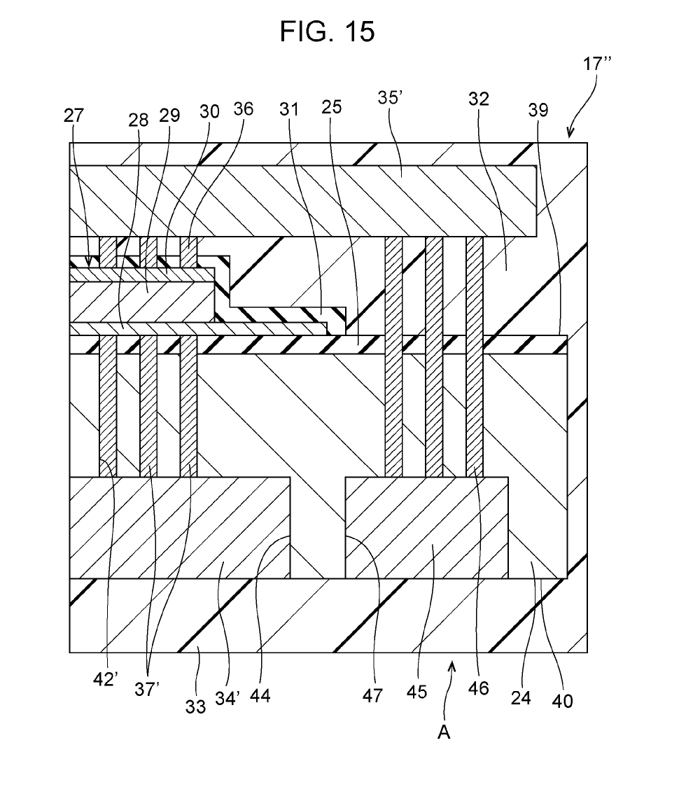

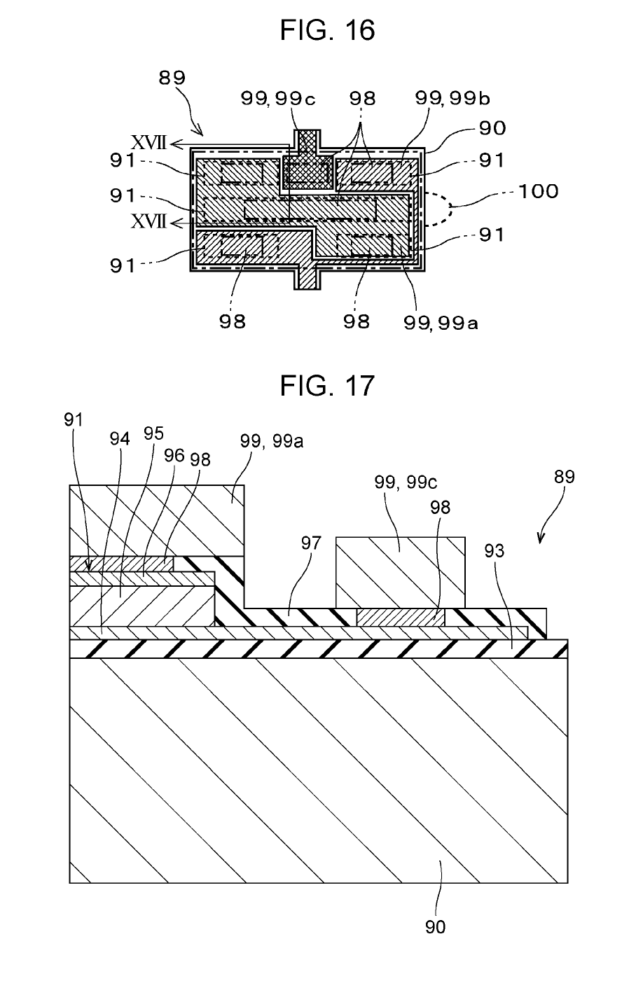

In each embodiment described above, although only the first wiring layer electrically connected to the first electrode layer 28 is disposed on the second surface 40, the invention is not limited thereto. In a piezoelectric actuator 17″ according to a third embodiment illustrated in FIG. 15, a third wiring layer 45 is formed on the second surface 40 which is electrically connected to the second wiring layer 35 in addition to the first wiring layer 34′.

Specifically, in the embodiment, in a region deviated from the piezoelectric element 27, a region A in which the first wiring layer 34′ is not formed is formed on a portion of the second surface 40. A third wiring layer 45 is formed on the region A. Like the first wiring layer 34′, in the embodiment, the third wiring layer 45 is formed on a recessed portion 47 in which the substrate 24 is recessed in the plate thickness direction. In other words, the third wiring layer 45 is buried in the recessed portion 47 formed at a position different from the recessed portion 44 in which the first wiring layer 34′ is buried. In addition, in the first surface 39 side, the second wiring layer 35′ extends to a position corresponding to the region facing the third wiring layer 45, that is, the region A. The second wiring layer 35′ and the third wiring layer 45 are connected to each other by the through wiring 46 passing through the substrate 24 and the first resin layer 32 between the substrate 24 and the second wiring layer 35′. In other words, the third wiring layer 45 is connected to the second electrode layer 30 via the through wiring 46 and the second wiring layer 35′. A diameter of the through wiring 46 is formed to be sufficiently smaller than the dimension of the piezoelectric element 27 in the longitudinal direction and the transverse direction, similarly to the through wiring 37′ connecting the first wiring layer 34′ and the first electrode layer 28. In addition, a plurality of through wirings 46 are formed on the region A. Accordingly, wiring resistance of the wiring can be suppressed by the wiring connected to the second electrode layer 30 being formed on the second surface 40 side. For example, on the circumstances of layout, in a case where wiring resistance of the second wiring layer 35′ is increased due to narrowing of the wiring width or thinning of the film thickness of a portion of the second wiring layer 35′, as in the embodiment, it is preferable that the second wiring layer 35′ be connected to the third wiring layer 45 and route in the second surface 40. Since other configurations are the same as those of the second embodiment described above, description thereof will be omitted. In addition, in the method for manufacturing the piezoelectric actuator 17″ according to the embodiment, since it is the same as in the second embodiment described above except that the through hole of the through wiring 46 is formed when the through hole 42′ of the through wiring 37′ is formed, the recessed portion 47 of the third wiring layer 45 is formed when the recessed portion 44 of the first wiring layer 34′ is formed, and the through wiring 46 and the third wiring layer 45 are formed when the through wiring 37′ and the first wiring layer 34′ are formed, the description thereof is omitted.

Incidentally, in each the embodiment described above, although the through wiring 37 connecting the first wiring layer 34 and the first electrode layer 28 and the contact hole 36 connecting the second electrode layer 30 and the second wiring layer 35 are uniformly disposed on a region overlapping the piezoelectric element 27 (that is, piezoelectric layer 29), the invention is not limited thereto. For example, these through wirings and contact holes may be gathered and disposed on a center portion of a region overlapping the piezoelectric element. In addition, a portion of the through wirings and the contact holes is formed on a region deviated from the piezoelectric element.

In addition, in each embodiment described above, although the piezoelectric actuator 17 used for the ultrasonic motor 1 is described as an example, the invention is not limited thereto. The present invention can also be applied to other piezoelectric actuators which have a piezoelectric element including the first electrode layer, the piezoelectric layer, and the second electrode layer, and deform the piezoelectric element. Further, the invention is not limited to the piezoelectric actuator, and the invention can be applied to any MEMS device in which the first electrode layer, the piezoelectric layer, and the second electrode layer are stacked. For example, the present invention can be also applied to a case where a piezoelectric element including the first electrode layer, the piezoelectric layer, and the second electrode layer is applied to a sensor for detecting pressure change, vibration, displacement, or the like.

What is claimed is:

1. A MEMS device in which a first electrode layer, a piezoelectric layer, and a second electrode layer are stacked in this order from a first surface side of a substrate,
wherein a first wiring layer is stacked on a second surface on a side opposite to a first surface of the substrate, and
wherein the first electrode layer and the first wiring layer are connected to each other via a through wiring passing through the substrate.

2. The MEMS device according to claim 1,
wherein the through wiring overlaps the piezoelectric layer in a stacking direction of the first electrode layer, the piezoelectric layer, and the second electrode layer.

3. The MEMS device according to claim 1,
wherein the through wiring overlaps a region in which the first electrode layer, the piezoelectric layer, and the second electrode layer overlap each other in the stacking direction.

4. The MEMS device according to claim 1,
wherein at least a portion of the first wiring layer is buried in the substrate.

5. The MEMS device according to claim 1,
wherein the first electrode layer and the first wiring layer are connected via a plurality of through wirings.

6. A MEMS device in which a first electrode layer, a piezoelectric layer, and a second electrode layer are stacked in this order from a first surface side of a substrate,
wherein a resin layer covering the first electrode layer, the piezoelectric layer, and the second electrode layer and a second wiring layer stacked at least on a portion of the resin layer are formed on the first surface of the substrate, and
wherein the second electrode layer and the second wiring layer are connected to each other via a contact hole formed on the resin layer.

7. The MEMS device according to claim 6,
wherein the contact hole overlaps the piezoelectric layer in a stacking direction of the first electrode layer, the piezoelectric layer, and the second electrode layer.

8. The MEMS device according to claim 6,
wherein at least a portion of the second wiring layer is buried in the resin layer.

9. The MEMS device according to claim 6,
wherein the second electrode layer and the second wiring layer are connected via the plurality of contact holes.

10. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 1.

11. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 2.

12. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 3.

13. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 4.

14. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 5.

15. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 6.

16. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 7.

17. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 8.

18. A piezoelectric actuator which deforms a piezoelectric layer by forming an electric field between a first electrode layer and a second electrode layer and deforms a substrate by deformation of the piezoelectric layer, comprising:
the structure of the MEMS device according to claim 9.

19. A ultrasonic motor including a protrusion of which position changes according to the deformation of a substrate; and a rotating object which abuts against the protrusion and rotates according to a change of the protrusion, comprising:
the structure of the piezoelectric actuator according to claim 10.

20. A ultrasonic motor including a protrusion of which position changes according to the deformation of a substrate; and a rotating object which abuts against the protrusion and rotates according to a change of the protrusion, comprising:
the structure of the piezoelectric actuator according to claim 11.
